(19) United States
(12) Patent Application Publication
(10) Pub. No.: US 2025/0251447 A1
(43) Pub. Date: Aug. 7, 2025

(54) METHOD OF TERMINATING UNUSED PORTS DURING CROSSTALK MEASUREMENT

(71) Applicant: The Curators of the University of Missouri, Columbia, MO (US)

(72) Inventors: Seyedmostafa Mousavi, Rolla, MO (US); Xiaoning Ye, Portland, OR (US); DongHyun Kim, Rolla, MO (US)

(73) Assignee: The Curators of the University of Missouri, Columbia, MO (US)

(21) Appl. No.: 19/047,361

(22) Filed: Feb. 6, 2025

Related U.S. Application Data
(60) Provisional application No. 63/550,816, filed on Feb. 7, 2024.

(51) Int. Cl. G01R 31/309; H05K 9/00

(52) U.S. Cl. CPC G01R 31/309; H05K 9/0081

(57) ABSTRACT

Methods for measuring crosstalk in an electronic circuit having multiple ports comprises determining two ports of interest of the electronic circuit, in which crosstalk will be measured between. Furthermore, the method includes determining one or more ports of the electronic circuit to be terminated, independent from the ports of interest, so that signals of these ports do not interfere with measuring crosstalk between the two ports of interest. To terminate the ports determined to be terminated, a piece of absorber sheet is used to cover the ports determined to be terminated. Pressure is applied to the piece of absorber sheet such that the piece of absorber sheet makes a good contact and absorbs signals traveling into the ports determined to be terminated, thereby terminating the ports determined to be terminated so that crosstalk between the two ports of interest may be effectively measured.

### CROSS-REFERENCE TO RELATED APPLICATION

This application claims the benefit of U.S. Provisional Application No. 63/550,816, filed Feb. 7, 2024, the entire disclosure of which is incorporated herein by reference.

### GOVERNMENT LICENSE RIGHTS

This invention was made with government support under 00065550 and 00072099 awarded by the National Science Foundation. The government has certain rights in the invention.

### FIELD

This disclosure pertains to a method for terminating unused ports to measure crosstalk between used ports.

### BACKGROUND

In signal integrity, crosstalk refers to undesirable capacitive, inductive, or conductive coupling or interference between adjacent conductors or traces on a printed circuit board of an electronic circuit or within a cable of an electronic circuit. Thus electrical systems with crosstalk present among components, are prone to signal distortion and degradation.

### SUMMARY

Aspects of the present disclosure permit an improved framework for terminating signals from unused ports to more effectively measure crosstalk between ports of interest.

In one aspect, a method for measuring crosstalk between two ports in an electronic circuit having a plurality of ports and a via structure associated with each of the plurality of ports comprises determining two ports of interest of the electronic circuit to measure crosstalk in between. Two or more ports of the electronic circuit are determined to be terminated, independent from the two ports of interest. The ports of the electronic circuit determined to be terminated are covered with a piece of absorber sheet. Pressure is applied to the piece of absorber sheet to create a contact to the via structure associated with each of the ports determined to be terminated such that the piece of absorber sheet absorbs electromagnetic signals traveling into the ports determined to be terminated, thereby terminating the ports determined to be terminated. Crosstalk is measured between the ports of interest.

In another aspect, a method for measuring crosstalk between two ports in an electronic circuit having a plurality of ports and a via structure associated with each of the plurality of ports comprises selecting two ports of interest of the electronic circuit to measure the cross talk in between. One or more ports of the electronic circuit are selected to be terminated, independent from the ports of interest. The ports of the electronic circuit determined to be terminated are covered with an absorber material. Pressure is applied to the absorber material to create a contact to the via structure associated with each of the ports determined to be terminated. The absorber material absorbs electromagnetic signals traveling into the ports determined to be terminated, thereby terminating the ports determined to be terminated. Crosstalk is measured between the ports of interest.

In another aspect, a method for mitigating crosstalk between two or more ports in an electronic circuit having a plurality of ports and a via structure associated with each of the plurality of ports comprises identifying two or more ports of the electronic circuit in use and potentially subject to crosstalk. One or more ports of the electronic circuit are selected to be terminated. The selected ports to be terminated are independent from and different than the identified in use ports. The one or more selected ports of the electronic circuit to be terminated are covered with an absorber material. Pressure is applied to the absorber material to create a contact to the via structure associated with each of the selected ports to be terminated. The absorber material absorbs electromagnetic signals traveling into the selected ports to be terminated, thereby terminating the selected ports to be terminated.

Other objects and features will be in part apparent and in part pointed out hereinafter.

### BRIEF DESCRIPTION OF THE DRAWINGS

FIG. 1A is a schematic diagram illustrating far end termination of a via of an unused port in far end crosstalk measurement according to an embodiment.

FIG. 1B is a schematic diagram illustrating near end termination of a via of an unused port in far end crosstalk measurement according to an embodiment.

FIG. 1C is a schematic diagram illustrating a single absorber sheet used as a termination during crosstalk measurement.

FIG. 2 is a graph illustrating an example simulation of far end crosstalk using conventional 500 terminations and using an absorber sheet as a termination according to an embodiment.

Corresponding reference characters indicate corresponding parts throughout the drawings.

### DETAILED DESCRIPTION

This disclosure generally pertains to methods for measuring and mitigating crosstalk between two ports in an electronic circuit comprising multiple ports. Measuring crosstalk is crucial for evaluating performance, reliability, and compliance of electronic circuits, whether in the design phase, during production, or when troubleshooting operational issues. Generally conventional procedures for measuring crosstalk between two ports include terminating other ports with coaxial 50 Ω terminations or soldering matching resistors to prevent interference with the measurement, and to create a controlled testing environment. The inventors have recognized several difficulties with conventional procedures, one difficulty being that employing matching resistors for unused port termination, results in limited frequency bandwidth due to undesirable parasitic components. Furthermore, conventional procedures introduce challenges related to resistor selection, soldering procedure, calibration, and potential interference. Additionally, as electronic circuits become more sophisticated, there is a corresponding increase in the number of ports or channels, leading to a greater level of intricacy in crosstalk measurements.

A method for measuring crosstalk embodying aspects of the present disclosure incorporates an absorber sheet with specified electromagnetic characteristics into a high-frequency electronic circuit to terminate traces ended with vias that represent ports in the electronic circuit. Furthermore, this method of the present disclosure is configured to minimize reflections, reduce interference, maintain signal integrity, ensure accurate and consistent measurements, and eliminate the need for soldering matching resistors or mounting coaxial terminations. As will be explained in further detail below, this method facilitates the measurement of crosstalk between various ports on an electronic circuit, thereby eliminating a need for separate test vehicles for crosstalk assessment.

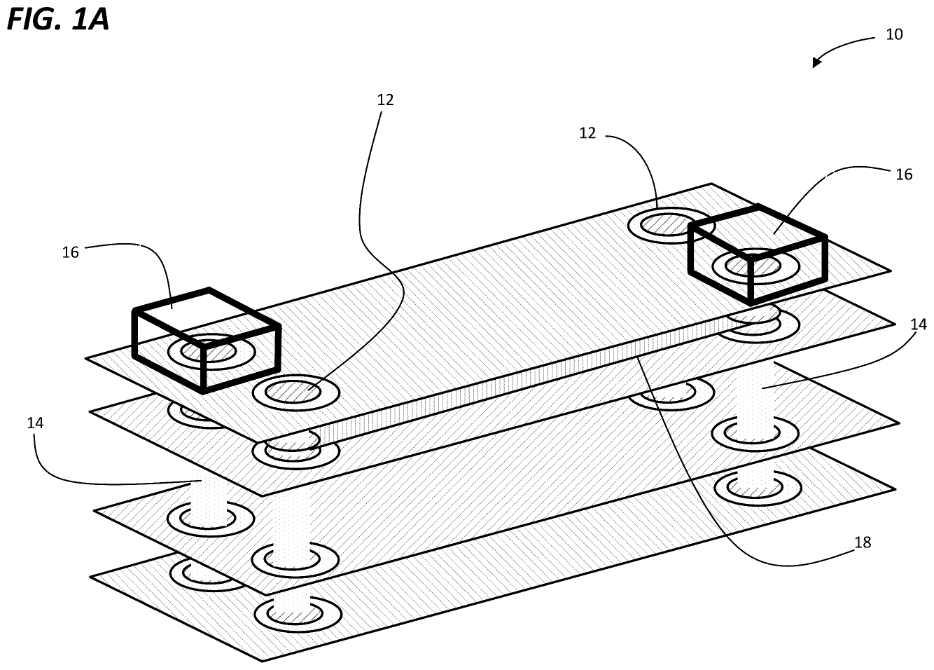

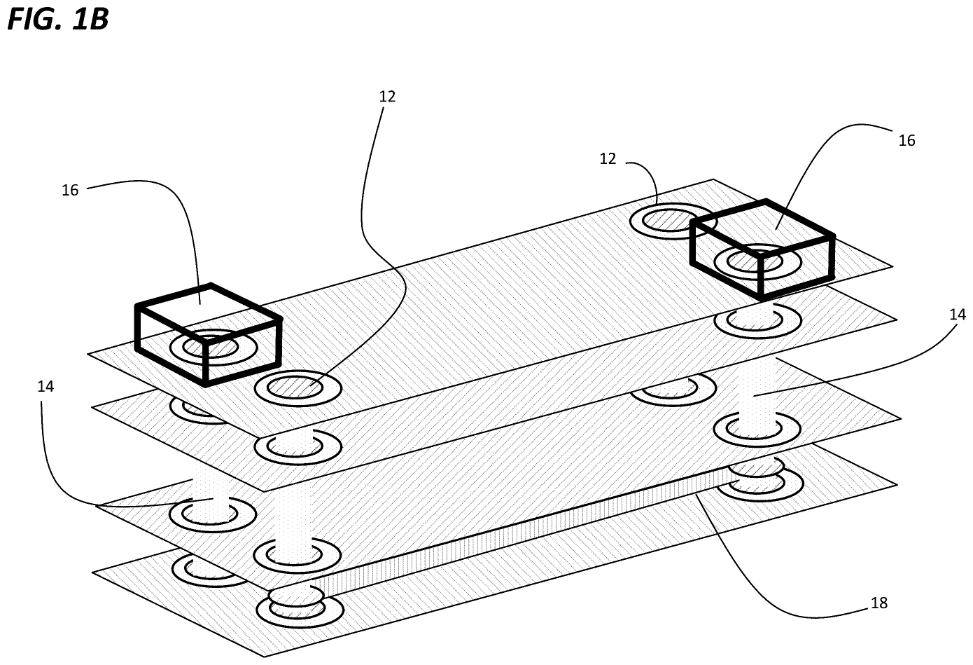

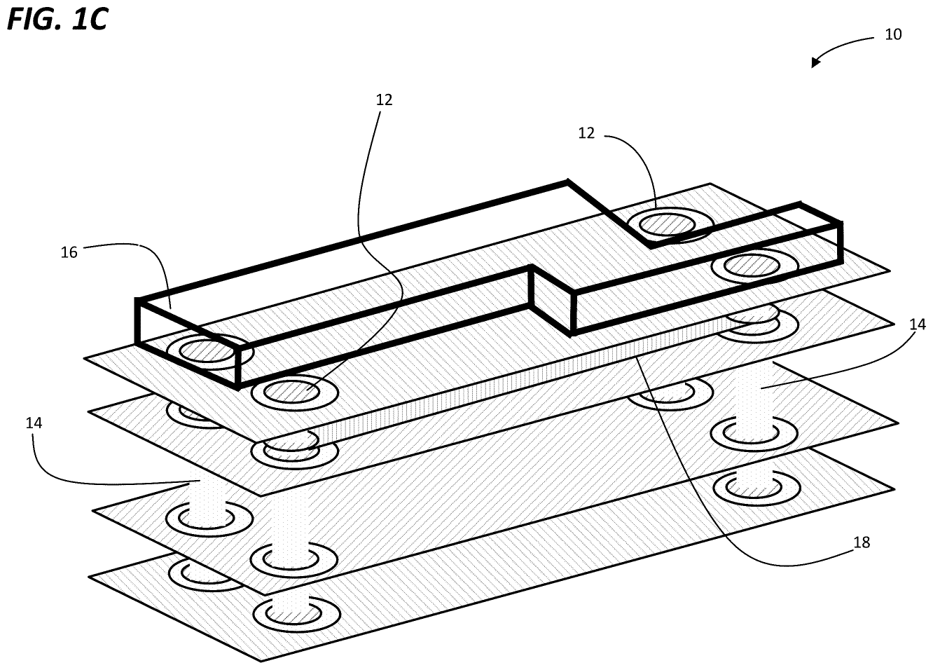

Referring now to FIGS. 1A-1C, an electronic circuit 10 (e.g., a high frequency electronic circuit) in accordance with the present disclosure, is shown comprising two ports of interest, referred to here as used ports 12 (e.g., channels or via structures), and unused ports 14 (e.g., channels or via structures. The unused ports 14 are selected for termination, and crosstalk is measured between the used ports 12. One or more absorber sheets 16 formed of absorber materials terminate the unused ports 14. One or more conductors 18 (e.g., stripline traces) are used to electrically connect at least one of the used ports 12 and unused ports 14. Particularly, FIG. 1A represents far end termination of unused via structures (ports) in far end crosstalk measurement (FEXT), and FIG. 1B represents near end termination of unused back drilled via structures in FEXT measurement. However, it is contemplated that the present disclosure may be implemented in near-end crosstalk measurement (NEXT) without departing from the scope of the present disclosure. FIG. 1C is an exemplary embodiment of the absorber sheet 16 comprising a single piece of monolithic material configured to terminate multiple unused ports 14. In an exemplary embodiment, the absorber sheet is a foam-like sheet formed of one or more absorber materials configured to provide an attenuation in an inclusive range from 22 dB/cm to 26 dB/cm at 3 GHz. However, other absorber sheet materials may be selected based on the operating conditions of the electronic circuit 10.

A method for measuring crosstalk between two ports in an electronic circuit having a plurality of ports such as the electronic circuits shown in FIGS. 1A-1C will now be described. Initially two or more ports of interest (e.g., used ports 12) within the electronic circuit 10 are determined for measuring crosstalk there between. Next, one or more unused ports 14 of the electronic circuit 10, independent from the two or more ports of interest 12, are selected for termination during the crosstalk measurement, so that the unused ports 14 do not interfere with the measurement. From here, the unused ports 14 determined or selected for termination are each covered with a piece of a specified absorber sheet 16. The absorber sheet 16 is pressed down to make a contact between the via structure so that the piece of absorber sheet absorbs signals (e.g., microwave frequency signals) traveling into the ports 14 determined to be terminated, thereby terminating the ports selected to be terminated. With these ports 14 determined for termination now terminated, crosstalk between the used ports 12 is measured.

A method for mitigating crosstalk between two or more ports in an electronic circuit having a plurality of ports such as the electronic circuits shown in FIGS. 1A-1C will now be described. Initially two or more ports of interest, or used, ports 12, within the electronic circuit 10 are determined. Next, the one or more unused ports 14 of the electronic circuit 10, independent from the two or more ports of interest 12, are determined or selected for termination. From here, the selected unused ports 14 are each covered with at least a piece of a specified absorber sheet 16. The absorber sheet 16 is pressed down to make a contact between the via structure so that the piece of absorber sheet 16 absorbs signals (e.g., microwave frequency signals) traveling into the ports 14 determined to be terminated, thereby terminating these ports 14. Thus crosstalk (e.g., near-end and far-end crosstalk) between the ports of interest 12 is mitigated.

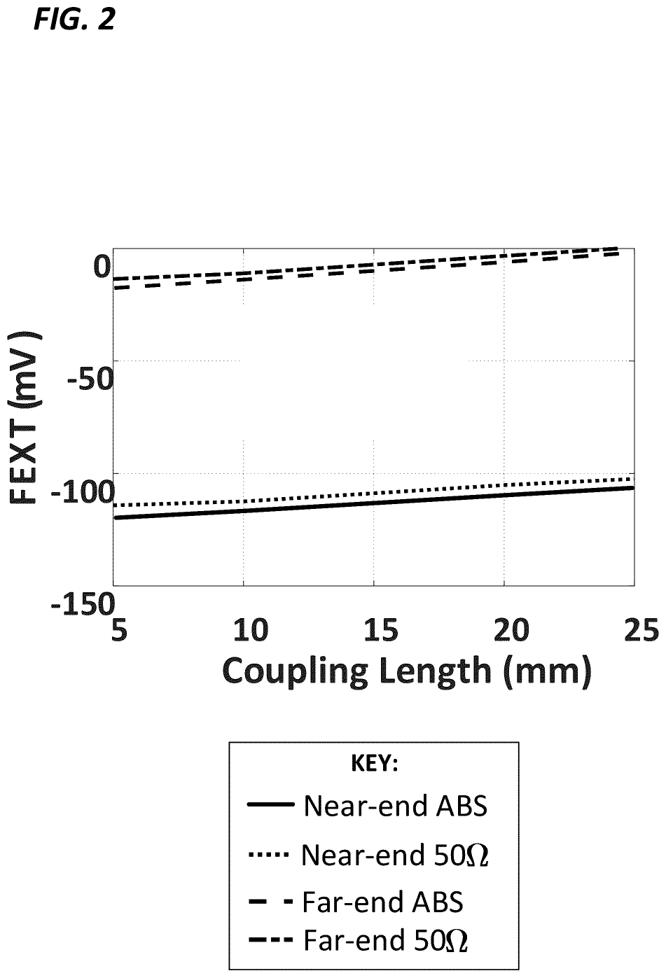

Investigating the method for measuring crosstalk in accordance with aspects of the present disclosure has revealed that utilizing absorber sheet 16 as a termination is effective for measuring crosstalk. Particularly, a full-wave simulation of crosstalk between two stripline-coupled traces was conducted, where unused ports 14 were terminated with matching loads (e.g., 50 Ω terminations) in accordance with conventional techniques compared to covering unused ports 14 by a designated absorber sheet (indicated by ABS), i.e., absorber sheet 16. As shown in FIG. 2, the simulation results demonstrate that the absorber sheet 16 can effectively function as a superior termination method for measuring crosstalk between coupled traces in high frequency printed circuit boards, as the crosstalk FEXT (mV) measured is significantly less when using the absorber sheet 16 as a termination as opposed to using 50 Ω terminations.

Advantageously, utilizing absorber sheet 16 as a termination for unused ports 14 eliminates a need for separate terminations on the printed circuit board layout for crosstalk evaluation. For example, FIG. 1C shows the absorber sheet 16 as a single sheet that may be used to terminate a plurality of unused ports 14. Accordingly, a method in accordance with further aspects of the present disclosure permits crosstalk measurement on commercial high-speed printed circuit boards without additional metal contact-based termination structures.

Having described the invention in detail, it will be apparent that modifications and variations are possible without departing from the scope of the invention defined in the appended claims.

When introducing elements of the present invention or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the invention are achieved and other advantageous results attained.

As various changes could be made in the above products without departing from the scope of the invention, it is intended that all matter contained in the above description and shown in the accompanying drawings shall be interpreted as illustrative and not in a limiting sense.

The Abstract and Summary are provided to help the reader quickly ascertain the nature of the technical disclosure. They are submitted with the understanding that they will not be used to interpret or limit the scope or meaning of the claims. The Summary is provided to introduce a selection of concepts in simplified form that are further described in the Detailed Description. The Summary is not intended to identify key features or essential features of the claimed subject matter, nor is it intended to be used as an aid in determining the claimed subject matter.

1. A method for measuring crosstalk between two ports in an electronic circuit, the electronic circuit having a plurality of ports and a via structure associated with each of the plurality of ports, the method comprising:
determining two ports of interest of the electronic circuit to measure crosstalk in between;
determining two or more ports of the electronic circuit to be terminated, independent from the two ports of interest;
covering the ports of the electronic circuit determined to be terminated with a piece of absorber sheet;
applying pressure to the piece of absorber sheet to create a contact to the via structure associated with each of the ports determined to be terminated such that the piece of absorber sheet absorbs electromagnetic signals traveling into the ports determined to be terminated, thereby terminating the ports determined to be terminated; and
measuring crosstalk between the ports of interest.

2. The method of claim 1, wherein said determining two or more ports of the electronic circuit to be terminated comprises selecting two or more unused ports.

3. The method of claim 1, wherein the electromagnetic signals comprise microwave frequency signals.

4. The method of claim 1, wherein the absorber sheet comprises a foam-like sheet.

5. The method of claim 1, wherein the absorber sheet is formed of one or more absorber materials having an attenuation in an inclusive range from 22 dB/cm to 26 dB/cm at 3 GHz.

6. The method of claim 1, wherein said covering the ports of the electronic circuit determined to be terminated comprises covering the ports of the electronic circuit determined to be terminated with a single piece of monolithic absorber sheet material configured to cover the ports of the electronic circuit determined to be terminated.

7. The method of claim 1, wherein said covering the ports of the electronic circuit determined to be terminated comprises covering each of the ports of the electronic circuit determined to be terminated with a separate piece of the absorber sheet.

8. The method of claim 1, wherein the electronic circuit comprises a high frequency electronic circuit.

9. The method of claim 1, further comprising assembling the electronic circuit.

10. The method of claim 1, wherein said measuring crosstalk between the ports of interest comprises measuring near-end crosstalk between the two ports of interest.

11. The method of claim 1, wherein said measuring crosstalk between the ports of interest comprises measuring far-end crosstalk between the two ports of interest.

12. A method for measuring crosstalk between two ports in an electronic circuit, the electronic circuit having a plurality of ports and a via structure associated with each of the plurality of ports, the method comprising:
selecting two ports of interest of the electronic circuit to measure the cross talk in between;
selecting one or more ports of the electronic circuit to be terminated, independent from the ports of interest;
covering the ports of the electronic circuit determined to be terminated with an absorber material;
applying pressure to the absorber material to create a contact to the via structure associated with each of the ports determined to be terminated, wherein the absorber material absorbs electromagnetic signals traveling into the ports determined to be terminated, thereby terminating the ports determined to be terminated; and
measuring crosstalk between the ports of interest.

13. The method of claim 12, wherein the absorber material comprises a portion of an absorber sheet.

14. A method for mitigating crosstalk between two or more ports in an electronic circuit, the electronic circuit having a plurality of ports and a via structure associated with each of the plurality of ports, the method comprising:
identifying two or more ports of the electronic circuit in use and potentially subject to crosstalk;
selecting one or more ports of the electronic circuit to be terminated, wherein the selected ports to be terminated are independent from and different than the identified in use ports;
covering the one or more selected ports of the electronic circuit to be terminated with an absorber material;
applying pressure to the absorber material to create a contact to the via structure associated with each of the selected ports to be terminated, wherein the absorber material absorbs electromagnetic signals traveling into the selected ports to be terminated, thereby terminating the selected ports to be terminated.

15. The method of claim 14, wherein said selecting one or more ports of the electronic circuit to be terminated comprises determining one or more ports of the electronic circuit not in use.

16. The method of claim 14, wherein the electromagnetic signals comprise microwave frequency signals.

17. The method of claim 14, wherein the absorber material comprises a portion of an absorber sheet.

18. The method of claim 14, wherein the absorber material comprises an absorber sheet comprising a single piece of monolithic material configured to cover the selected ports of the electronic circuit to be terminated.

19. The method of claim 14, wherein the absorber material comprises a foam-like sheet.

20. The method of claim 14, wherein the absorber material comprises an attenuation in an inclusive range from 22 dB/cm to 26 dB/cm at 3 GHz.
